(19) United States
(12) Patent Application Publication
(10) Pub. No.: US 2026/0191116 A1
(43) Pub. Date: Jul. 2, 2026

(54) DUAL-COMPRESSION CONTACT SOCKET FOR MEMORY ON INTEGRATED CIRCUIT DEVICE PACKAGES

(71) Applicant: Intel Corporation, Santa Clara, CA (US)

(72) Inventors: Jiun Hann Sir, Gelugor (MY); Eng Huat Goh, Penang (MY); Telesphor Kamgaing, Chandler, AZ (US); Poh Boon Khoo, Perai (MY)

(73) Assignee: Intel Corporation, Santa Clara, CA (US)

(21) Appl. No.: 19/003,997

(22) Filed: Dec. 27, 2024

(51) Int. Cl. H01L 23/498; H01L 21/48; H01L 23/00; H01L 23/24; H01L 23/40; H01L 25/18; H10B 80/00; H10D 80/30

(52) U.S. Cl. CPC H10W 90/701; H10B 80/00; H10W 70/023; H10W 90/00; H10D 80/30; H10W 40/233; H10W 40/60; H10W 46/00; H10W 76/47; H10W 80/312; H10W 80/327; H10W 90/20; H10W 90/288; H10W 90/792; H10W 90/794

(57) ABSTRACT

An apparatus is provided which comprises: a substrate, the substrate including traces and one or more conductive substrate contacts on a first substrate surface, a computing device on a second substrate surface opposite the first substrate surface, the computing device conductively coupled with the substrate contacts through the traces, a socket on the first substrate surface, the socket including a plastic body, the plastic body including one or more holes through the plastic body, the socket including one or more conductive socket contacts extending beyond a first and a second side of the plastic body through the one or more holes, a memory device on the socket, the memory device including one or more conductive memory device contacts, and a fastener to mechanically hold the memory device contacts in contact with the socket contacts and the socket contacts in contact with the substrate contacts. Other embodiments also disclosed and claimed.

### BACKGROUND

Computing platforms, such as desktops, laptops or smart phones, for example, are expected to have increased performance compared with previous iterations. One way that manufacturers of computing platforms can achieve increased performance is by integrating more integrated circuit devices into a single package. Heterogeneous integration refers to the integration of separately manufactured components into an assembly that, in the aggregate, provides enhanced functionality and improved operating characteristics. As more computing cores are integrated into a package, or system on a chip, there arises a need to integrate more memory components into the package as well. With increased integration, there can arise issues with signal routing and integrity, performance, and circuit board size within device packages. Therefore, there is a need for high performance architectures that address these issues.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIGS. 1A & 1B illustrate a plan view and a cross-sectional view, respectively, of an example dual-compression contact socket for memory on integrated circuit device packages, according to some embodiments;

FIGS. 2A & 2B illustrate cross-sectional views of example manufacturing steps of forming a socket contact for a dual-compression contact socket for memory on integrated circuit device packages, according to some embodiments;

FIGS. 3A and 3B illustrate cross-sectional views of example manufacturing steps of forming a dual-compression contact socket for memory on integrated circuit device packages, according to some embodiments;

FIGS. 4A-4F illustrate cross-sectional views of example manufacturing steps of assembling a dual-compression contact socket for memory on integrated circuit device packages, according to some embodiments;

FIG. 5 illustrates a cross-sectional view of an example dual-compression contact socket for memory on integrated circuit device packages, in accordance with some embodiments;

FIG. 6 illustrates a flowchart of an example method of assembling a dual-compression contact socket for memory on integrated circuit device packages, in accordance with some embodiments; and

FIG. 7 illustrates a smart device or a computer system or a SoC (System-on-Chip) which includes a dual-compression contact socket for memory on integrated circuit device packages, according to some embodiments.

### DETAILED DESCRIPTION

Dual-compression contact sockets for memory on integrated circuit device packages are generally presented. In this regard, embodiments of the present disclosure enable more memory to be included in close proximity to computing devices/cores. One skilled in the art would appreciate that these dual-compression contact sockets may enable higher performance with some increase in package dimensions. Additionally, the architectures described herein may offer improved thermal management, signal integrity, warpage, and flexibility, and thereby enable enhanced features.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

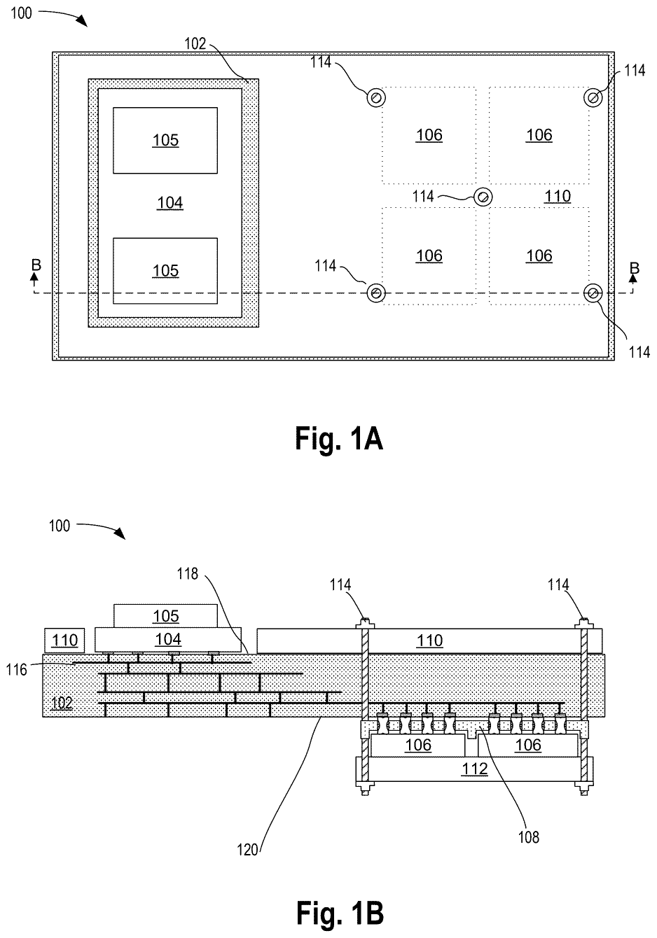

FIGS. 1A & 1B illustrate a plan view and a cross-sectional view, respectively, of an example dual-compression contact socket for memory on integrated circuit device packages, according to some embodiments. As shown, device package 100 includes package substrate 102, integrated circuit devices 104 and 105, memory devices 106, socket 108, stiffener plate 110, heat spreader 112, fastener pins 114, conductive routing 116, substrate top surface 118, and substrate bottom surface 120. In some embodiments, device package 100 may include additional layers and integrate additional components.

In some embodiments, integrated circuit devices 104 and 105 may represent controllers, processors, or system-on-a-chip (SOCs), such as multi-core processors, for example. As shown, integrated circuit device 104 may represent a base die with top dies 105 stacked on top. In some embodiments, integrated circuit devices 104 and 105 may be implemented as a stack of multiple homogeneous or heterogeneous devices. In some embodiments, integrated circuit devices 104 and 105 may be surrounded by an epoxy underfill (not shown).

In some embodiments, integrated circuit devices 104 and 105 may be coupled through traditional solder bonding. In other embodiments, integrated circuit devices 104 and 105 may be coupled through hybrid bonding. In some embodiments, integrated circuit devices 104 and 105 may be coupled through a direct chip to chip interconnect using high bandwidth interconnect (HBI).

In some embodiments, package substrate 102 may represent any type of substrate material, including, for example, organic or inorganic materials with or without core layers for mechanical stability. In some embodiments, package substrate 102 may include a combination of multiple substrate materials, including silicon with through silicon vias (TSVs).

In some embodiments, memory devices 106 may be discrete memory devices, such as a double data rate (DDR), a high bandwidth memory (HBM), a low power double data rate (LPDDR), or a fast page mode (FPM), for example.

In some embodiments, socket 108 may be a dual-compression contact socket as described in more detail hereinafter. In some embodiments, socket 108 has contacts that span from substrate bottom surface 120 to memory devices 106. In some embodiments, socket 108 is not permanently attached with substrate bottom surface 120, but is instead held in contact by mechanical forces from a fastener, such as pressure applied by memory devices 106 from heat spreader 112 and fastener pins 114, for example. In other embodiments, other fasteners may be utilized to hold socket 108 in contact with substrate bottom surface 120 and memory devices 106 in contact with socket 108. In some embodiments, socket 108 has stanchions with openings to allow fastener pins 114 to pass through.

In some embodiments, stiffener plate 110 may be present and may be metal or another solid material and may provide mechanical support to package substrate 102. In some embodiments, stiffener plate 110 may have openings to allow fastener pins 114 to pass through. As shown, stiffener plate 110 may extend to or near an edge of package substrate 102. Also as shown, and in some embodiments, stiffener plate 110 may surround four sides of integrated circuit devices 104 and 105.

In some embodiments, heat spreader 112 may be metal or another solid material and may have heat conductive properties to remove heat from and also apply mechanical forces against memory devices 106. In some embodiments, heat spreader 112 may have openings to allow fastener pins 114 to pass through.

In some embodiments, fastener pins 114 may be metal or another solid material and may have threaded ends onto which threaded caps may be tightened. In some embodiments, fastener pins 114 provide mechanical forces against stiffener plate 110 and heat spreader 112, thereby maintaining conductive contact between substrate bottom surface 120, socket 108, and memory devices 106.

In some embodiments, conductive routing 116 may include multiple layers of interlayer dielectric, such as organic dielectric, for example, along with metal wires to route between contacts of integrated circuit devices 104 and memory devices 106. In some embodiments, conductive routing 116 may fan-in a contact pitch from a substrate bottom surface 120 and memory devices 106 to substrate top surface 118 and integrated circuit devices 104.

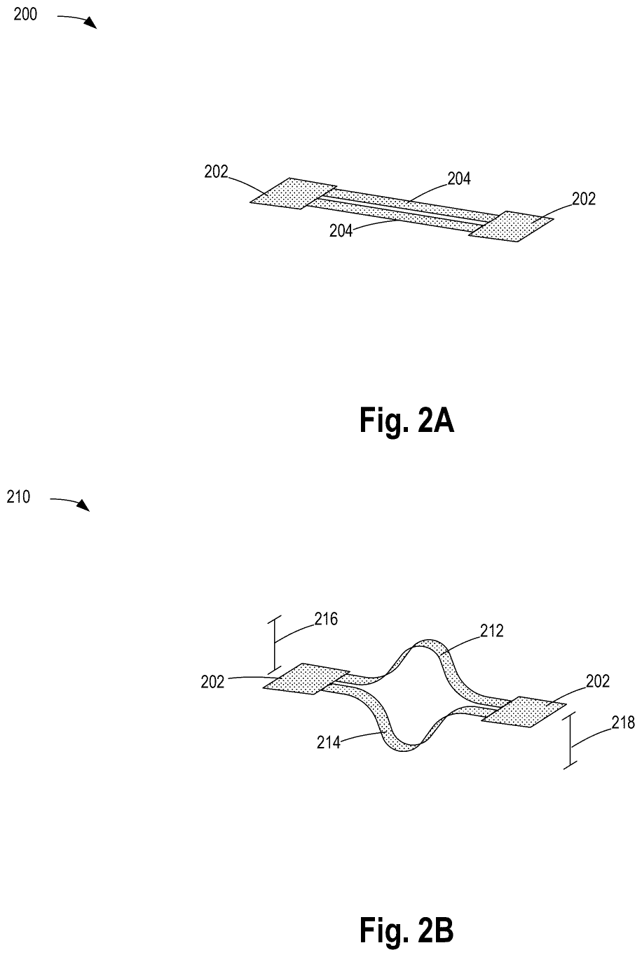

FIGS. 2A & 2B illustrate cross-sectional views of example manufacturing steps of forming a socket contact for a dual-compression contact socket for memory on integrated circuit device packages, according to some embodiments. As shown in FIG. 2A, contact 200 includes pads 202, and beams 204. In some embodiments, contact 200 may be copper or another conductive metal. As shown, pads 202 may be square pads connected by rectangular beams 204, however, pads 202 and beams 204 may be other shapes or sizes.

FIG. 2B shows contact 210, which may include pads 202, and deformed beams 212 and 214. In some embodiments, contact 210 may result from mechanical deforming or shaping of beams 204 of contact 200 in opposite directions. In some embodiments, deformed beam 212 may extend a distance 216 from pads 202, while deformed beam 214 may extend a distance 218 from pads 202. In some embodiments, distance 216 may be equal to distance 218. While shown as having a curved shape, deformed beams 212 and 214 may be less curved and more angular or some other shape.

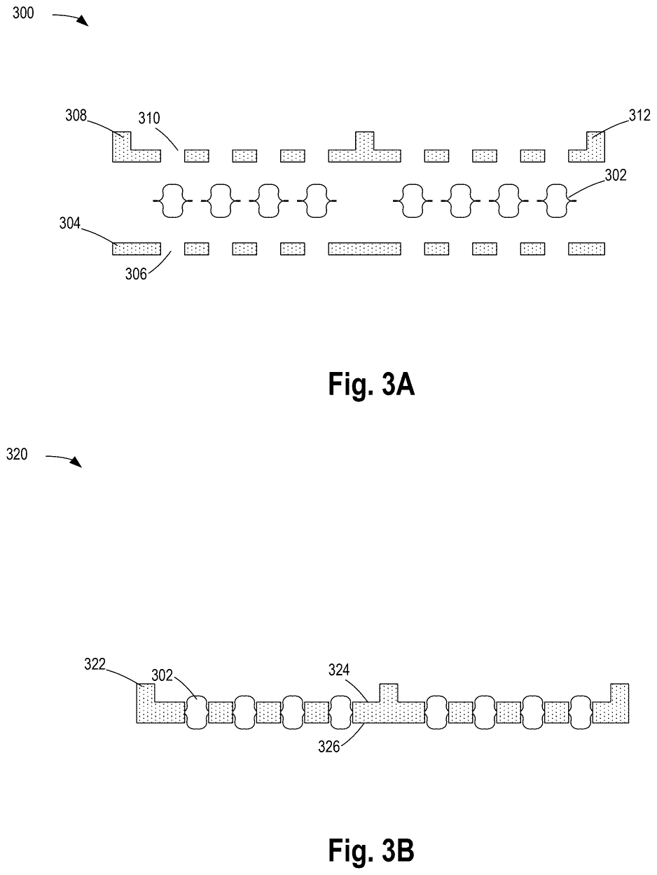

FIGS. 3A & 3B illustrate cross-sectional views of example manufacturing steps of forming a dual-compression contact socket for memory on integrated circuit device packages, according to some embodiments. As shown in FIG. 3A, assembly 300 includes contacts 302, first plastic body 304, plastic body openings 306, second plastic body 308, plastic body openings 310, and plastic body stanchion 312. In some embodiments, contacts 302 may be preformed pieces of copper, or other conductive material, including any of the properties mentioned previously, for example in reference to FIGS. 2A and 2B, for example, contacts 210.

In some embodiments, first plastic body 304 and second plastic body 308 may be a rigid plastic, and may include a series of openings 306 and 310, respectively, which may be large enough to allow deformed beams of contacts 302 to pass through, and small enough to capture pads of contacts 302. In some embodiments, second plastic body 308 may include plastic body stanchions 312, which may include openings for fastener pins and may correspond in height to a memory device.

FIG. 3B shows assembly 320, which may include contacts 302, plastic body 322, plastic body upper surface 324, and plastic body lower surface 326. In some embodiments, plastic body 322 may be the result of adhering first plastic body 304 and second plastic body 308, for example with the use of adhesive. In some embodiments, contacts 302 may include curved beams that extend in opposite directions beyond plastic body upper surface 324 and plastic body lower surface 326.

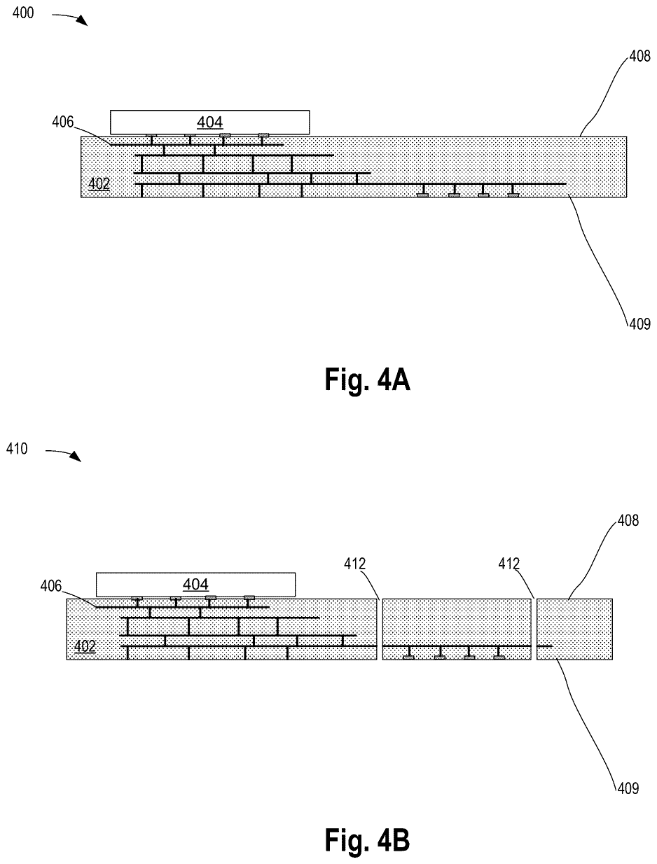

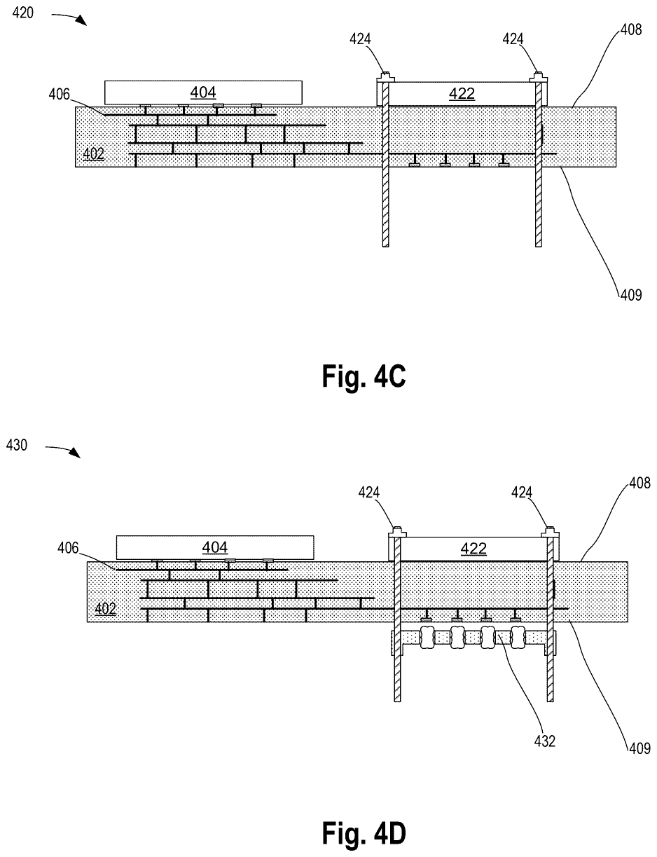

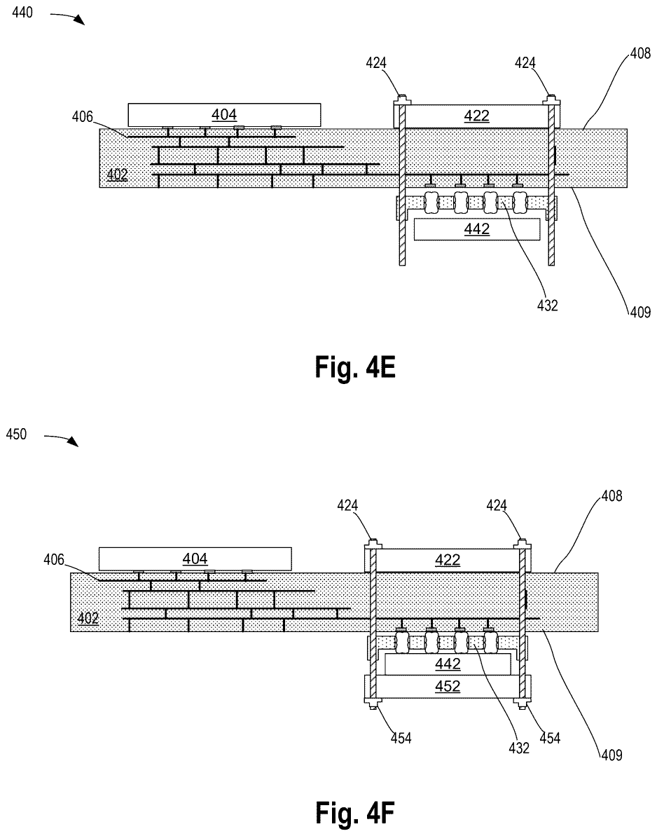

FIGS. 4A-4F illustrate cross-sectional views of example manufacturing steps of assembling a dual-compression contact socket for memory on integrated circuit device packages, according to some embodiments. As shown in FIG. 4A, assembly 400 includes substrate 402, integrated circuit device 404, traces 406, upper substrate surface 408, and lower substrate surface 409. While shown as including a single integrated circuit device 404, any number of integrated circuit devices or other devices may be present.

FIG. 4B shows assembly 410, which may include openings 412 formed through substrate 402. In some embodiments, openings 412 may be formed by mechanical means, such as drilling, or by other means.

As shown in FIG. 4C, assembly 420 includes stiffener plate 422, and fastener pins 424. In some embodiments, fastener pins 424 may pass through openings 412 and stiffener plate 422. In other embodiments, fastener pins 424 may be incorporated into stiffener plate 422.

Turning now to FIG. 4D, assembly 430 may include socket 432. In some embodiments, socket 432 may include any of the properties mentioned previously, for example in reference to FIGS. 3A and 3B. In some embodiments, socket 432 may include stanchions with openings through which fastener pins 424 may pass.

FIG. 4E shows assembly 440, which may include memory device 442. In some embodiments, memory device 442 may include contacts aligned with contacts of socket 432.

As shown in FIG. 4F, assembly 450 may include heat spreader 452 and retention caps 454. In some embodiments, heat spreader 452 may include openings through which fastener pins 424 may pass. In some embodiments, retention caps 454 may be threaded caps that twist onto threads of fastener pins 424, which in other embodiments retention caps 454 may adhere with fastener pins 424 in other ways.

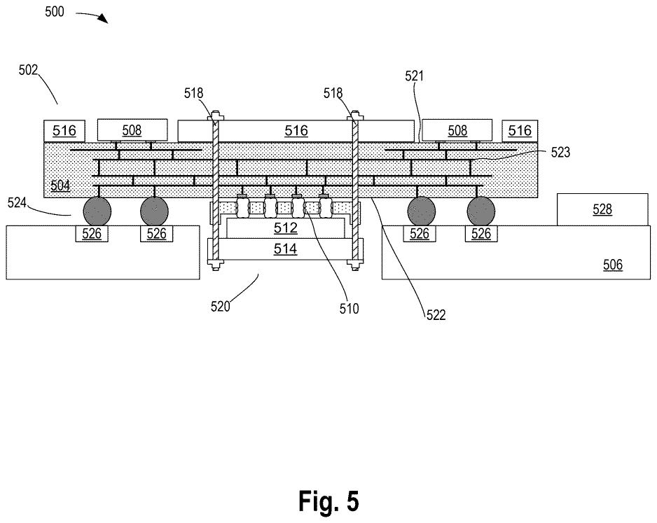

FIG. 5 illustrates a cross-sectional view of an example dual-compression contact socket for memory on integrated circuit device packages, according to some embodiments. As shown, assembly 500 includes device package 502, package substrate 504, system board 506, integrated circuit devices 508, socket 510, memory device 512, heat spreader 514, stiffener plate 516, retention pins 518, system board opening 520, substrate top surface 521, substrate bottom surface 522, traces 523, solder balls 524, board pads 526, and board component 528.

Device package 502 may incorporate elements previously discussed in reference to prior figures. For example, device package 502 may have properties discussed previously in reference to FIGS. 1A, 1B, 2A, 2B, 3A, 3B, or 4A-4F. As shown, device package 502 may include multiple integrated circuit devices 508 on substrate top surface 521, however, device package 502 may include other devices in other configurations, for example, multiple integrated circuit devices coupled through an embedded multi-die interconnect bridge.

In some embodiments, solder balls 524 may be formed on device package surface 522, thereby allowing device package 502 to be soldered to system board 506 through board pads 526. System board 506 may also incorporate board component 528, which may represent any type of active or passive system components, such as a power supply, memory devices, voltage regulators, I/O interfaces, etc.

In some embodiments, system board opening 520 may be formed in system board 506 by any known method, such as mechanical drilling, for example. In some embodiments, system board opening 520 may be large enough to accommodate heat spreader 514, memory device 512, and socket 510, which may extend into system board opening 520.

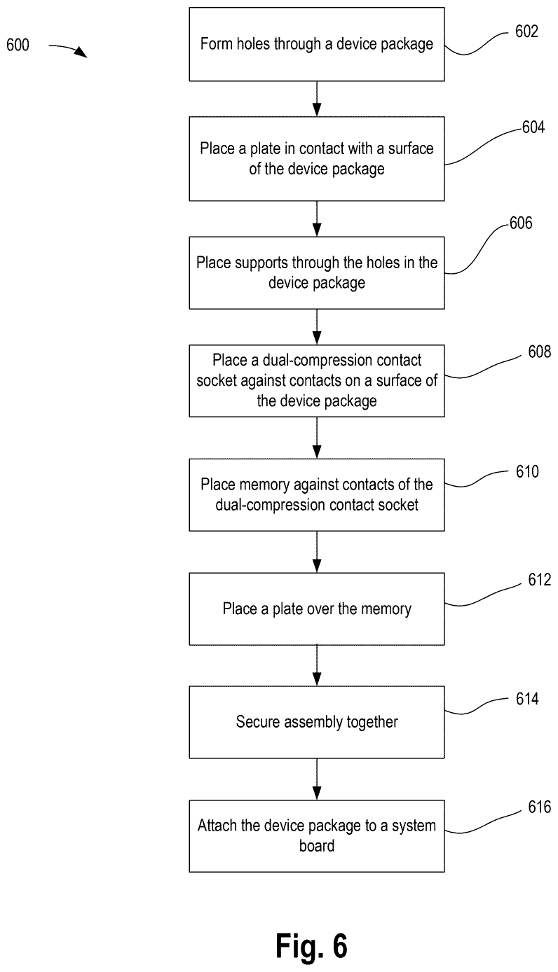

FIG. 6 illustrates a flowchart of an example method of assembling a dual-compression contact socket for memory on integrated circuit device packages, in accordance with some embodiments. Although the blocks in the flowchart with reference to FIG. 6 are shown in a particular order, the order of the actions can be modified. Thus, the illustrated embodiments can be performed in a different order, and some actions/blocks may be performed in parallel. Some of the blocks and/or operations listed in FIG. 6 are optional in accordance with certain embodiments. The numbering of the blocks presented is for the sake of clarity and is not intended to prescribe an order of operations in which the various blocks must occur. Additionally, operations from the various flows may be utilized in a variety of combinations.

Method 600 begins with forming (602) holes through a device package. In some embodiments, such as assembly 410, openings 412 may be formed through substrate 402. Next, a plate may be placed (604) in contact with a surface of the device package. In some embodiments, such as assembly 420, stiffener plate 422 may be placed on upper substrate surface 408.

Then, supports may be placed (606) through the holes in the device package. In some embodiments, such as assembly 420, fastener pins 424 may be inserted through openings 412 in substrate 402. Next, a dual-compression contact socket may be placed (608) against contacts on a surface of the device package. In some embodiments, such as assembly 430, socket 432 may be placed against contacts on lower substrate surface 409.

The method continues, in some embodiments, with placing memory (610) against contacts of the dual-compression contact socket. In some embodiments, such as assembly 440, memory device 442 may be placed against contacts of socket 432. Next, a plate may be placed (612) over the memory. In some embodiments, such as assembly 450, heat spreader 452 may be placed over memory device 442.

Next, the assembly may be secured (614) together. In some embodiments, such as assembly 450, caps 454 may be secured to fastener pins 424 to secure heat spreader 452, memory device 442, socket 432, substrate 402, and stiffener plate 422. Finally, the device package may be attached (616) to a system board. In some embodiments, such as assembly 500, device package 502 may be attached to system board 506.

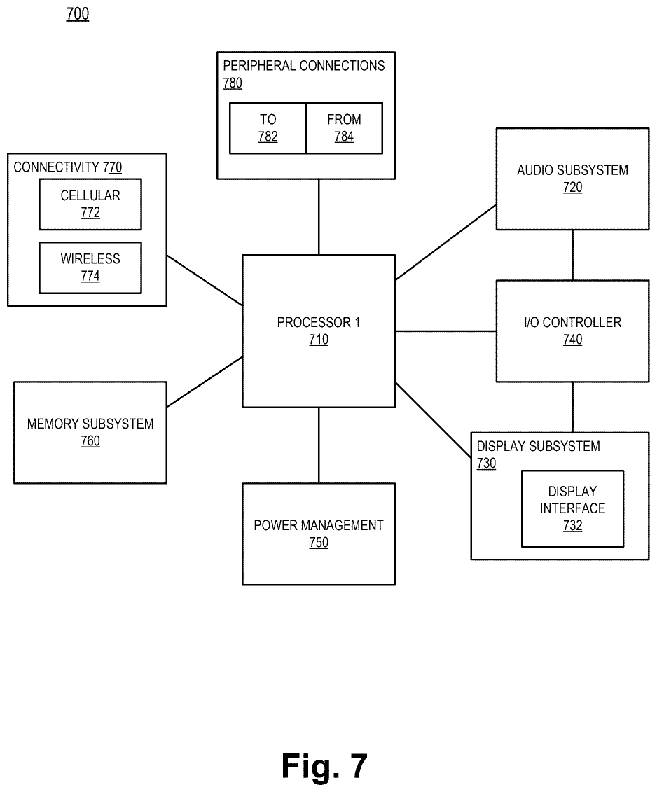

FIG. 7 illustrates a smart device or a computer system or a SoC (System-on-Chip) which includes a dual-compression contact socket for memory on integrated circuit device packages, according to some embodiments. In some embodiments, computing device 700 represents a mobile computing device, such as a computing tablet, a mobile phone or smartphone, a wireless-enabled e-reader, or other wireless mobile device. It will be understood that certain components are shown generally, and not all components of such a device are shown in computing device 700. In some embodiments, one or more components of computing device 700, for example processor 710 or I/O controller 740, include a dual-compression contact socket for memory on an integrated circuit device package as described above.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, etc., may be used without departing from the scope of the disclosure.

In some embodiments, computing device 700 includes a first processor 710. The various embodiments of the present disclosure may also comprise a network interface within 770 such as a wireless interface so that a system embodiment may be incorporated into a wireless device, for example, cell phone or personal digital assistant.

In one embodiment, processor 710 can include one or more physical devices, such as microprocessors, application processors, microcontrollers, programmable logic devices, or other processing means. The processing operations performed by processor 710 include the execution of an operating platform or operating system on which applications and/or device functions are executed. The processing operations include operations related to I/O (input/output) with a human user or with other devices, operations related to power management, and/or operations related to connecting the computing device 700 to another device. The processing operations may also include operations related to audio I/O and/or display I/O.

In one embodiment, computing device 700 includes audio subsystem 720, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 700, or connected to the computing device 700. In one embodiment, a user interacts with the computing device 700 by providing audio commands that are received and processed by processor 710.

Display subsystem 730 represents hardware (e.g., display devices) and software (e.g., drivers) components that provide a visual and/or tactile display for a user to interact with the computing device 700. Display subsystem 730 includes display interface 732, which includes the particular screen or hardware device used to provide a display to a user. In one embodiment, display interface 732 includes logic separate from processor 710 to perform at least some processing related to the display. In one embodiment, display subsystem 730 includes a touch screen (or touch pad) device that provides both output and input to a user.

I/O controller 740 represents hardware devices and software components related to interaction with a user. I/O controller 740 is operable to manage hardware that is part of audio subsystem 720 and/or display subsystem 730. Additionally, I/O controller 740 illustrates a connection point for additional devices that connect to computing device 700 through which a user might interact with the system. For example, devices that can be attached to the computing device 700 might include microphone devices, speaker or stereo systems, video systems or other display devices, keyboard or keypad devices, or other I/O devices for use with specific applications such as card readers or other devices.

As mentioned above, I/O controller 740 can interact with audio subsystem 720 and/or display subsystem 730. For example, input through a microphone or other audio device can provide input or commands for one or more applications or functions of the computing device 700. Additionally, audio output can be provided instead of, or in addition to display output. In another example, if display subsystem 730 includes a touch screen, the display device also acts as an input device, which can be at least partially managed by I/O controller 740. There can also be additional buttons or switches on the computing device 700 to provide I/O functions managed by I/O controller 740.

In one embodiment, I/O controller 740 manages devices such as accelerometers, cameras, light sensors or other environmental sensors, or other hardware that can be included in the computing device 700. The input can be part of direct user interaction, as well as providing environmental input to the system to influence its operations (such as filtering for noise, adjusting displays for brightness detection, applying a flash for a camera, or other features).

In one embodiment, computing device 700 includes power management 750 that manages battery power usage, charging of the battery, and features related to power saving operation. Memory subsystem 760 includes memory devices for storing information in computing device 700. Memory can include nonvolatile (state does not change if power to the memory device is interrupted) and/or volatile (state is indeterminate if power to the memory device is interrupted) memory devices. Memory subsystem 760 can store application data, user data, music, photos, documents, or other data, as well as system data (whether long-term or temporary) related to the execution of the applications and functions of the computing device 700.

Elements of embodiments are also provided as a machine-readable medium (e.g., memory 760) for storing the computer-executable instructions. The machine-readable medium (e.g., memory 760) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 770 includes hardware devices (e.g., wireless and/or wired connectors and communication hardware) and software components (e.g., drivers, protocol stacks) to enable the computing device 700 to communicate with external devices. The computing device 700 could be separate devices, such as other computing devices, wireless access points or base stations, as well as peripherals such as headsets, printers, or other devices.

Connectivity 770 can include multiple different types of connectivity. To generalize, the computing device 700 is illustrated with cellular connectivity 772 and wireless connectivity 774. Cellular connectivity 772 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 774 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 780 include hardware interfaces and connectors, as well as software components (e.g., drivers, protocol stacks) to make peripheral connections. It will be understood that the computing device 700 could both be a peripheral device (“to” 782) to other computing devices, as well as have peripheral devices (“from” 784) connected to it. The computing device 700 commonly has a “docking” connector to connect to other computing devices for purposes such as managing (e.g., downloading and/or uploading, changing, synchronizing) content on computing device 700. Additionally, a docking connector can allow computing device 700 to connect to certain peripherals that allow the computing device 700 to control content output, for example, to audiovisual or other systems.

In addition to a proprietary docking connector or other proprietary connection hardware, the computing device 700 can make peripheral connections 780 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An apparatus comprising:
a substrate, the substrate including traces and one or more conductive substrate contacts on a first substrate surface;
a computing device on a second substrate surface opposite the first substrate surface, the computing device conductively coupled with the substrate contacts through the traces;
a socket on the first substrate surface, the socket including a plastic body, the plastic body including one or more holes through the plastic body, the socket including one or more conductive socket contacts extending beyond a first and a second side of the plastic body through the one or more holes;
a memory device on the socket, the memory device including one or more conductive memory device contacts; and
a fastener to mechanically hold the memory device contacts in contact with the socket contacts and the socket contacts in contact with the substrate contacts.

2. The apparatus of claim 1, wherein the fastener comprises two or more pins extending through the substrate with caps affixed to ends of the pins.

3. The apparatus of claim 2, further comprising a plate on the memory device between the caps.

4. The apparatus of claim 1, wherein the socket contacts comprise curved contacts.

5. The apparatus of claim 4, wherein the socket contacts comprise two beams deflected in opposite directions.

6. The apparatus of claim 1, wherein the memory device comprises a technology chosen from the group consisting of: double data rate (DDR), high bandwidth memory (HBM), low power double data rate (LPDDR), and fast page mode (FPM).

7. The apparatus of claim 1, further comprising one or more additional memory devices in contact with the socket and a heat spreader.

8. A system comprising:
a host board;
an integrated circuit device package, the integrated circuit device package comprising:
a substrate, the substrate including traces and one or more conductive substrate contacts on a first substrate surface;
a computing device on a second substrate surface opposite the first substrate surface, the computing device conductively coupled with the substrate contacts through the traces;
a socket on the first substrate surface, the socket including a plastic body, the plastic body including one or more holes through the plastic body, the socket including one or more conductive socket contacts extending beyond a first and a second side of the plastic body through the one or more holes;
a memory device on the socket, the memory device including one or more conductive memory device contacts; and
a fastener to mechanically hold the memory device contacts in contact with the socket contacts and the socket contacts in contact with the substrate contacts; and
a power supply to provide power to the integrated circuit device package through the host board.

9. The system of claim 8, wherein the memory device extends into an opening in the host board.

10. The system of claim 8, wherein the fastener comprises two or more pins extending through the substrate with caps affixed to ends of the pins.

11. The system of claim 10, further comprising a plate on the second substrate surface between the caps to provide mechanical support.

12. The system of claim 8, wherein the socket contacts comprise two beams deflected in opposite directions.

13. The system of claim 8, wherein the memory device comprises a technology chosen from the group consisting of: double data rate (DDR), high bandwidth memory (HBM), low power double data rate (LPDDR), and fast page mode (FPM).

14. The system of claim 8, further comprising one or more additional memory devices in contact with the socket and a heat spreader.

15. A method comprising:
placing socket contacts that extend beyond a first side of a socket against contacts on a first surface of a device package, wherein the device package includes one or more computing devices on a second surface of the device package;
placing a memory device against socket contacts that extend beyond a second side of the socket;
placing a heat spreader against the memory device; and
securing the heat spreader against the memory device.

16. The method of claim 15, further comprising placing a plate against the second surface of the device package opposite the contacts on the first surface of the device package.

17. The method of claim 15, wherein securing the heat spreader against the memory device comprises securing caps on pins that extend through openings in the device package.

18. The method of claim 17, further comprising the pins extending through openings in the socket.

19. The method of claim 17, wherein securing the caps comprises twisting threaded caps on the pins.

20. The method of claim 15, further comprising attaching the device package to a system board, wherein the memory device extends within an opening in the system board.
